(19) United States
(12) Patent Application Publication
(10) Pub. No.: US 2026/0267133 A1
(43) Pub. Date: Sep. 10, 2026

(54) ADAPTIVE OPTICAL MODULE FOR A MICROLITHOGRAPHIC PROJECTION EXPOSURE APPARATUS

(71) Applicant: Carl Zeiss SMT GmbH, Oberkochen (DE)

(72) Inventors: Toralf GRUNER, Aalen (DE); Markus RAAB, Schillingsfuerst (DE); Hans Michael STIEPAN, Aalen (DE); Axel WITT, Rheinstetten (DE)

(21) Appl. No.: 19/663,810

(22) Filed: Apr. 30, 2026

Related U.S. Application Data
(63) Continuation of application No. PCT/EP2024/079792, filed on Oct. 22, 2024.

(30) Foreign Application Priority Data
Nov. 3, 2023 (DE) 10 2023 210 952.2

(51) Int. Cl. G02B 26/08; G01B 7/16; G03F 7/00

(52) U.S. Cl. CPC G02B 26/0825; G01B 7/16; G03F 7/70266; G03F 7/70525; G03F 7/70533; G03F 7/70825; G03F 7/7085; G03F 7/7095; G03F 7/70991

(57) ABSTRACT

An adaptive optical module for a microlithographic projection exposure system comprises: an optical surface for interacting with exposure radiation of the projection exposure system; and a plurality of actuators for modifying a shape of the optical surface. The adaptive optical module comprises a dielectric medium that can be deformed by applying an electric voltage. Each of the actuators comprises a separate control electrode which in each case is designed to generate an electric field in a layer of the dielectric medium. The control electrodes are connected to one another via a weakly conductive structure having an electrical conductivity of at least 0.1 mS/m. In order to measure an impedance of at least one of the actuators, a measurement electrode is between the control electrode of the actuator being measured and the dielectric medium.

### CROSS-REFERENCE TO RELATED APPLICATIONS

The present application is a continuation of, and claims benefit under 35 USC 120 to, international application No. PCT/EP2024/079792, filed Oct. 22, 2024, which claims benefit under 35 USC 119 of German Application No. 10 2023 210 952.2, filed Nov. 3, 2023. The entire disclosure of each of these applications is incorporated by reference herein.

### FIELD

The disclosure relates to an adaptive optical module for a microlithographic projection exposure apparatus having a plurality of actuators, a microlithographic projection exposure apparatus having such an adaptive optical module, and a method for ascertaining a respective displacement of a plurality of actuators of an adaptive optical module of a microlithographic projection exposure apparatus.

### BACKGROUND

A projection lens of a microlithographic projection exposure apparatus with wavefront aberrations that are as small as reasonably possible is often used to try to ensure imaging of the mask structures on the wafer as precisely as reasonably possible. Therefore, projection lenses are often equipped with manipulators that allow the correction of wavefront aberrations by changing the state of individual optical elements of the projection lens. Examples of such a change of state comprise a change of pose in one or more of the six rigid-body degrees of freedom of the relevant optical element and a deformation of the optical element.

For the latter change of state, the optical element is usually integrated into an adaptive optical module of the aforementioned type. The latter may comprise one or more piezoelectric or electrostrictive actuators for the purpose of actuating the optical surface. The functionality of such actuators is often based on the deformation of a dielectric medium by the application of an electric field. To determine the desired change of state, the aberration characteristic of the projection lens is usually measured regularly and, if appropriate, changes in the aberration characteristic between the individual measurements are determined by simulation. Thus, it is possible to take account of e.g. lens or mirror heating effects by calculation.

When using piezoelectric or electrostrictive adaptive optical elements, changes of relevant parameters in the actuator material, for instance on account of temperature variations, aging, defects, drifts, etc., may lead to significant inaccuracies in the surface shape corrections carried out by the adaptive optical element.

In order to correct or avoid these inaccuracies, DE 10 2020 212 743 A1, for example, proposes arranging in the actuator material a measuring electrode that serves for temperature measurement, and carrying out corresponding corrections on the basis of the measurement result. However, this is an indirect measurement of the surface shape errors caused by actuator deviations, and its accuracy is often insufficient.

### SUMMARY

The disclosure seeks to provide an adaptive optical module and a method of the type mentioned in the introduction that allow the aforementioned problems to be solved and, for example, allow a surface shape correction of the adaptive optical element to be implemented with improved accuracy.

In a first aspect, the disclosure provides an adaptive optical module for a microlithographic projection exposure apparatus. The adaptive optical module comprises an optical surface for interaction with an exposure radiation of the projection exposure apparatus and a plurality of actuators for changing a shape of the optical surface. Furthermore, the adaptive optical module comprises a dielectric medium, which is deformable by application of an electrical voltage, and each of the actuators comprises a separate control electrode, which in each case is arranged to generate a respective electric field in a layer of the dielectric medium. Furthermore, the control electrodes are connected to one another via a weakly conductive structure having an electrical conductivity of at least 0.1 mS/m, i.e. 10⁻⁴ S/m, and, for measuring an impedance of at least one of the actuators, a measuring electrode is arranged between the control electrode of the actuator being measured, i.e. the actuator with regard to which the impedance is measured, and the dielectric medium. The actuator being measured should be understood to mean the actuator being measured with regard to the impedance.

In accordance with one embodiment, a respective measuring electrode for measuring an impedance of the respective actuator is arranged between the respective control electrode and the dielectric medium. The weakly conductive structure should be understood to mean a weakly electrically conductive structure. In accordance with one embodiment, the conductivity of the weakly conductive structure can be at least 0.1 mS/m, i.e. 0.0001 siemens/meter, and less than 1 kS/m. In accordance with further embodiments, the conductivity of the weakly conductive structure is at least 1 mS/m, at least 0.01 S/m, at least 0.1 S/m or at least 10 S/m. The upper limit for the conductivity of the weakly conductive structure can be 1 kS/m, 200 S/m or 100 S/m in accordance with various embodiments.

For example, the weakly conductive structure is designed as a layer, and the actuators are electrically coupled by the weakly conductive structure. In other words, the actuators can thus be used in coupled networks in order to smooth the deformation effect when individual actuators are controlled. The use of the weakly conductive structure creates a gradient field between the electrodes of the actuators. The indication that each of the actuators has a separate control electrode should be understood to mean that each actuator has a dedicated control electrode, i.e. the actuators do not share a single control electrode.

The electric field is generated in the layer of the dielectric medium by application of an electrical voltage to the dielectric medium. This causes a deformation of the dielectric medium. The respective measuring electrode is arranged for measuring the impedance of the respective actuator, i.e. the impedance of the actuator assigned to the relevant control electrode. The impedance can be measured during the operation of the projection exposure apparatus or else in exposure pauses.

The first aspect allows the determination of a deflection of at least one of the actuators at at least one operating point on the basis of an impedance measurement, i.e. an electrical measurement on the adaptive optical module. In comparison with an interferometric measurement of the surface shape on the basis of the working voltage, for example, the electrical measurement according to the disclosure can be carried out with a high repetition rate, optionally even during the exposure operation of a microlithographic projection exposure apparatus.

The disclosure provides the insight that, when using the control electrode of an actuator to be measured for impedance measurement, falsifications in the measurement result may arise on account of the connection of this control electrode to control electrodes of adjacent actuators via the weakly conductive structure. These falsifications may be caused by leakage currents between the control electrodes occurring during impedance measurement. In order to exclude this source of error, in accordance with the first aspect according to the disclosure at least one measuring electrode can be arranged between the control electrode of the actuator being measured and the dielectric medium. This measuring electrode has no electrical connection to an electrode of an adjacent actuator, for example to one of the control electrodes or to a further measuring electrode of an adjacent actuator. The adaptive optical module configured in accordance with the first aspect according to the disclosure can thus allow a measurement of a deflection of at least one of the actuators with a high repetition rate and at the same time a high accuracy. This can allow a surface shape correction of the adaptive optical element to be carried out with a high accuracy. In this text, an adjacent actuator with respect to a reference actuator should be understood to mean any actuator whose control electrode is connected to the control electrode of the reference actuator via the weakly conductive layer. The term “adjacent actuator” thus covers both an actuator that directly neighbors the reference actuator, i.e. an actuator that is directly adjacent to the reference actuator, and a next but one or more remote actuator neighbor.

In accordance with embodiments, the weakly conductive structure is configured as a layer arranged between the control electrodes of the actuators and the dielectric medium.

In accordance with embodiments, the layer of the weakly conductive structure extends continuously along the control electrodes of the actuators.

In accordance with embodiments, the adaptive optical module furthermore comprises at least one base electrode arranged as a counterelectrode with respect to the control electrodes and configured to generate, together with the respective control electrode, the respective electric field in the dielectric medium. A common base electrode or a plurality of base electrodes can be provided for the various actuators.

In a second aspect, the disclosure provides an adaptive optical module for a microlithographic projection exposure apparatus. The adaptive optical module comprises an optical surface for interaction with an exposure radiation of the projection exposure apparatus and a plurality of actuators for changing a shape of the optical surface. Furthermore, the adaptive optical module comprises a dielectric medium, which is deformable by application of an electrical voltage, and each of the actuators comprises a separate control electrode, which in each case is arranged to generate an electric field in a layer of the dielectric medium. Furthermore, the control electrodes are connected to one another via a weakly conductive structure having an electrical conductivity of at least 0.1 mS/m. Furthermore, the adaptive optical module comprises an evaluation device configured, during the measurement of an impedance of at least one of the actuators, to computationally extract from the measurement result an effect—influencing the measurement result—of a current flow between the control electrode of the actuator being measured and at least one further of the control electrodes, the current flow being caused by the weakly conductive structure.

The further of the control electrodes can be a control electrode directly adjacent to the control electrode being measured. In accordance with embodiments, for each measured impedance of the actuators, the relevant current flow between the control electrode of the actuator being measured and at least one further of the control electrodes is computationally extracted from the measurement result on the basis of at least one predetermined coupling resistance between the control electrodes. The current flows between the control electrodes can take place substantially or completely via the weakly conductive structure.

In accordance with embodiments, a respective measuring electrode for measuring an impedance of the respective actuator is arranged between the respective control electrode and the dielectric medium. The weakly conductive structure should be understood to mean a weakly electrically conductive structure. In accordance with embodiments, the conductivity of the weakly conductive structure can be at least 0.1 mS/m, i.e. 0.0001 siemens/meter, and less than 1 kS/m. In accordance with embodiments, the conductivity of the weakly conductive structure is at least 1 mS/m, at least 0.01 S/m, at least 0.1 S/m or at least 10 S/m. The upper limit for the conductivity of the weakly conductive structure can be 1 kS/m, 200 S/m or 100 S/m in accordance with various embodiments.

The second aspect according to the disclosure allows—like the solution in accordance with the first aspect according to the disclosure—the determination of a deflection of at least one of the actuators at at least one operating point on the basis of an impedance measurement, i.e. an electrical measurement on the adaptive optical module. For impedance measurement, the control electrode of an actuator to be measured can be used in this case. As already explained above with reference to the solution in accordance with the first aspect according to the disclosure, such an electrical measurement can be carried out with a high repetition rate, optionally even during exposure operation of a microlithographic projection exposure apparatus.

The disclosure furthermore provides insight that falsifications in the measurement result may arise on account of leakage currents on account of the electrical connection of this control electrode to control electrodes of adjacent actuators via the weakly conductive structure. These falsifications can be avoided in accordance with the second aspect according to the disclosure by way of computationally extracting from the measurement result an effect—influencing the measurement result—of a current flow between the control electrode of the actuator being measured and at least one further of the control electrodes, the current flow being caused by the weakly conductive structure. The adaptive optical module configured in accordance with the second aspect according to the disclosure can thus allow a measurement of a deflection of at least one of the actuators with a high repetition rate and at the same time a high accuracy. This can allow a surface shape correction of the adaptive optical element to be carried out with a high accuracy.

In accordance with embodiments according to the second aspect according to the disclosure, the adaptive optical module comprises at least one current measuring device for measuring the current flow between the control electrode of the actuator being measured and the at least one further of the control electrodes, wherein the evaluation device is configured to computationally extract the effect from the measurement result on the basis of the measured current flow.

In accordance with embodiments according to the second aspect according to the disclosure, there is adjacent, for example directly adjacent, to the control electrode of the actuator being measured at least four, for example at least eight, control electrodes of further actuators, and the adaptive optical module comprises a respective current measuring device for measuring the respective current flow between the control electrode of the actuator being measured and each of the adjacent control electrodes. Furthermore, the evaluation device is configured to computationally extract the respective effect of the measured current flows from the measurement result.

In accordance with embodiments according to the second aspect according to the disclosure, the weakly conductive structure comprises a plurality of sections, wherein one each of the sections is arranged on the control electrode of the actuator being measured and on the at least one further control electrode and the two sections are electrically conductively connected via the current measuring device.

In accordance with embodiments according to the second aspect according to the disclosure, the sections of the weakly conductive structure are electrically insulated from one another, for example by an insulating separation line, with the exception of the connection via the current measuring device.

In accordance with embodiments according to the second aspect according to the disclosure, one each of the sections of the weakly conductive structure is arranged on the control electrode of the actuator being measured and on the control electrodes of all actuators directly adjacent to the actuator being measured and the section of the actuator being measured is electrically conductively connected to each of the sections arranged on the directly adjacent actuators via a dedicated current measuring device.

In accordance with embodiments according to the second aspect according to the disclosure, the evaluation device is furthermore configured to computationally extract from the measurement result the effect on the basis of at least one predetermined coupling resistance between the control electrode of the actuator being measured and the at least one further control electrode. In accordance with embodiments, there is adjacent, for example adjacent, to the control electrode of the actuator being measured at least four, for example at least eight, control electrodes of further actuators, and the evaluation device is configured to computationally extract from the measurement result the respective effect of predetermined coupling resistances between the control electrode of the actuator being measured and the adjacent control electrodes.

In accordance with embodiments according to the second aspect according to the disclosure, the adaptive optical module comprises at least one current measuring device for measuring a current flow emerging from the further control electrode when a test voltage is applied to the control electrode of the actuator being measured.

In accordance with embodiments according to the second aspect according to the disclosure, the adaptive optical element comprises at least one voltage source connected to at least one of the control electrodes, wherein the evaluation device is configured, during the measurement of the impedance of the at least one control electrode, to computationally extract from the measurement result a line resistance from the voltage source to the control electrode. In the general case, the adaptive optical module comprises an impedance measuring device configured to measure the impedance of the at least one control electrode. Such an impedance measuring device can also impress a current and measure the voltage, instead of the use of a voltage source.

In accordance with embodiments according to the second aspect according to the disclosure, the adaptive optical module comprises an AC voltage source configured, for the purpose of determining the line resistance of the at least one control electrode, to apply to the at least one control electrode an AC voltage having such a high frequency that an equivalent ohmic resistance of the actuator assigned to the control electrode decreases to less than 10%, for example to less than 5%, of the value of the line resistance. For example, the frequency can be at least 10 kHz, for example at least 100 kHz or at least 500 kHz. Here, too, the adaptive optical module in the general case can comprise an impedance measuring device which impresses an alternating current, instead of an AC voltage source.

In accordance with embodiments according to the second aspect according to the disclosure, the adaptive optical module furthermore comprises a measuring device configured, during the measurement of the respective impedance of the actuators, to measure a current intensity flowing away from the respective control electrode. During the measurement of the impedance, an AC voltage is applied to the respective control electrode and the current intensity flowing away from the respective control electrode is measured.

In accordance with embodiments according to the first or second aspect according to the disclosure, the adaptive optical module furthermore comprises an evaluation device configured to calculate an actuator deflection from a measured impedance of one of the actuators. This is done for example by determining a dielectric susceptibility of the relevant actuator from the measured impedance and performing a linear mapping to determine the actuator deflection.

In accordance with embodiments, the adaptive optical module furthermore comprises a control unit configured to correct a control variable present at the assigned control electrode on the basis of the calculated actuator deflection.

In accordance with embodiments according to the first or second aspect according to the disclosure, the weakly conductive structure comprises a rare-earth nickel oxide. The weakly conductive structure can comprise at least 90% of the rare-earth nickel oxide, such as completely consisting of the rare-earth nickel oxide. In accordance with embodiment variants, the rare-earth nickel oxide comprises LaNiO₃, which may also be referred to as LNO.

Furthermore, the disclosure provides a microlithographic projection exposure apparatus comprising at least one adaptive optical module in accordance with one of the embodiments or embodiment variants according to the first or second aspect according to the disclosure.

Furthermore, in accordance with the first aspect according to the disclosure, a method for ascertaining a respective deflection of a plurality of actuators of an adaptive optical module of a microlithographic projection exposure apparatus is provided, which are configured for changing a shape of an optical surface of the optical module. In this case, the adaptive optical module can comprise a dielectric medium, which is deformable via an electrical voltage, each of the actuators optionally comprising a separate control electrode for generating a respective electric field in a layer of the dielectric medium, the control electrodes are connected to one another via a weakly conductive structure having an electrical conductivity of at least 0.1 mS/m, and the method can comprise the steps of: measuring an impedance of at least one of the actuators via a measuring electrode arranged between the control electrode of the actuator being measured and the dielectric medium, and calculating the respective deflection of the actuators from the respective measured impedance.

Furthermore, in accordance with the second aspect according to the disclosure, a method for ascertaining a respective deflection of a plurality of actuators of an adaptive optical module of a microlithographic projection exposure apparatus is provided, the actuators being configured for changing a shape of an optical surface of the optical module. In this case, the adaptive optical module can comprise a dielectric medium, which is deformable via an electrical voltage, with each of the actuators optionally comprising a separate control electrode for generating a respective electric field in a layer of the dielectric medium, the control electrodes optionally being connected to one another via a weakly conductive structure having an electrical conductivity of at least 0.1 mS/m, and the method optionally comprising the steps of: measuring an impedance of at least one of the actuators, computationally extracting an effect of a current flow caused by the weakly conductive structure from the measurement result of the impedance measurement, wherein the current flow takes place between the control electrode of the actuator being measured and at least one further of the control electrodes, and calculating the respective deflection of the actuators from the respective measured impedance.

In accordance with embodiments of the method according to the second aspect according to the disclosure, the current flow caused by the weakly conductive structure is measured via a current measuring device and computationally extracting the effect from the measurement result of the impedance measurement is carried out on the basis of the measured current flow.

In accordance with embodiments according to the second aspect according to the disclosure, a coupling resistance between the control electrode of the actuator is measured and the at least one further control electrode is determined and computationally extracting the effect from the measurement result of the impedance measurement is carried out on the basis of the determined coupling resistance. In other words, the determination of the coupling resistance is carried out before computationally extracting the effect from the measurement result.

In accordance with embodiments according to the second aspect according to the disclosure, a line resistance of at least one electrical connection between at least one voltage source and at least one of the control electrodes is determined by there being applied to the control electrode an AC voltage having such a high frequency that an equivalent ohmic resistance of the actuator assigned to the control electrode decreases to less than 10% of the value of the line resistance. The determined line resistance can be computationally extracted from the measurement result during the measurement of the impedance of the control electrode.

In accordance with embodiments according to the first or second aspect according to the disclosure, computationally extracting the effect of a current flow caused by the weakly conductive structure from the measurement result of the impedance measurement is carried out during operation of the projection exposure apparatus for the exposure of a substrate. In other words, the computational extraction is carried out in a period of time that begins with the exposure of a first field on the substrate, also referred to as wafer, and ends with the exposure of the last field on the substrate. That is to say that the computational extraction can be carried out during the exposure of one or more fields or else in the short exposure pauses between the exposure of the fields. The entire method for ascertaining a respective deflection of a plurality of actuators of an adaptive optical module in accordance with the first or the second aspect according to the disclosure can be carried out during operation of the projection exposure apparatus for the exposure of a substrate.

The features indicated with regard to the above-specified embodiments, exemplary embodiments or embodiment variants, etc., of the adaptive optical module according to the first or second aspect according to the disclosure can be applied, mutatis mutandis, to the method according to the disclosure according to the first or respectively second aspect according to the disclosure, and vice versa. These and other features of the embodiments according to the disclosure are explained in the description of the figures and in the claims. The individual features may be implemented either separately or in combination as embodiments of the disclosure. Furthermore, they may describe certain embodiments that are independently protectable and protection for which is claimed only during or after pendency of the application, as the case may be.

### BRIEF DESCRIPTION OF THE DRAWINGS

The aforementioned features and further features of the disclosure are elucidated in the following detailed description of exemplary embodiment examples or embodiments according to the disclosure with reference to the appended schematic drawings, in which:

FIG. 1 shows one embodiment of a microlithographic EUV projection exposure apparatus having an adaptive optical module;

FIG. 2 shows one embodiment of the adaptive optical module in accordance with FIG. 1 in an initial state and in a correction state;

FIG. 3 shows one embodiment of the adaptive optical module in accordance with a first aspect according to the disclosure with an exemplary cross-sectional view of a layer construction having three actuators arranged next to one another and an electronics unit;

FIG. 4 shows one embodiment of the adaptive optical module in accordance with a second aspect according to the disclosure with an exemplary cross-sectional view of a layer construction having three actuators arranged next to one another and an electronics unit;

FIG. 5 shows the adaptive optical module in accordance with FIG. 4 in a further sectional view illustrating respective control electrodes of the actuators from above;

FIG. 6 shows an equivalent circuit diagram of the actuators of one embodiment of the adaptive optical module in accordance with the second aspect according to the disclosure as illustrated in FIG. 8;

FIG. 7 shows the equivalent circuit diagram in accordance with FIG. 6, in which line resistances are additionally taken into account;

FIG. 8 shows a further embodiment of the adaptive optical module in accordance with a second aspect according to the disclosure with an exemplary cross-sectional view of a layer construction having three actuators arranged next to one another and an electronics unit; and

FIG. 9 shows a view of a microlithographic DUV projection exposure apparatus having an adaptive optical module.

### DETAILED DESCRIPTION

In the exemplary embodiments or embodiments or embodiment variants described below, elements that are functionally or structurally similar to one another are provided with the same or similar reference signs as far as reasonably possible. Therefore, for understanding the features of the individual elements of a specific exemplary embodiment, reference should be made to the description of other exemplary embodiments or the general description of the disclosure.

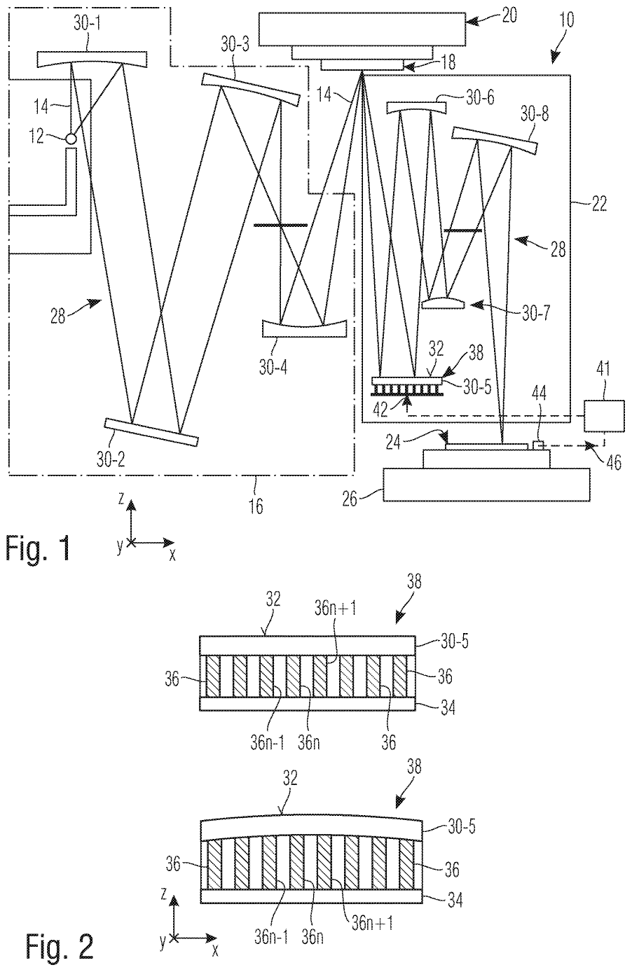

In order to facilitate the description, a Cartesian xyz-coordinate system is indicated in the drawing, from which system the respective positional relationship of the components illustrated in the figures is evident. In FIG. 1, the y-direction runs perpendicularly to the plane of the drawing into the plane, the x-direction runs toward the right and the z-direction runs upward.

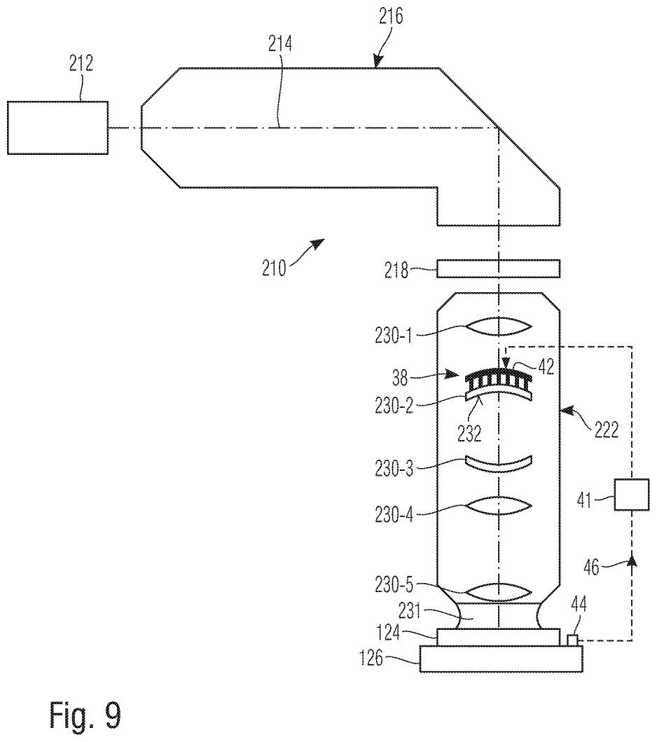

FIG. 1 shows one embodiment according to the disclosure of a microlithographic projection exposure apparatus 10. The present embodiment is designed for operation in the EUV wavelength range, i.e. with electromagnetic radiation at a wavelength of shorter than 100 nm, for example a wavelength of approximately 13.5 nm or approximately 6.8 nm. All optical elements are embodied as mirrors as a result of this operating wavelength. However, the disclosure is not limited to projection exposure apparatuses in the EUV wavelength range. Further embodiments according to the disclosure are designed for example for operating wavelengths in the UV range, such as 365 nm, 248 nm or 193 nm. In that case, at least some of the optical elements are configured as conventional transmission lens elements, as illustrated by way of example in FIG. 9 described further below.

The projection exposure apparatus 10 in accordance with FIG. 1 comprises an exposure radiation source 12 for generating exposure radiation 14. In the present case, the exposure radiation source 12 is embodied as an EUV source and can comprise for example a plasma radiation source. The exposure radiation 14 initially passes through an illumination optical unit 16 and is directed by the latter onto a mask 18.

The mask 18 comprises mask structures, which are imaged onto a substrate 24 in the form of a wafer during exposure operation of the projection exposure apparatus 10, and is displaceably mounted on a mask displacement stage 20. The substrate 24 is displaceably mounted on a substrate displacement stage 26. As illustrated in FIG. 1, the mask 18 can be embodied as a reflection mask, or alternatively, especially for UV lithography, it can also be configured as a transmission mask. In the embodiment in accordance with FIG. 1, the exposure radiation 14 is reflected at the mask 18 and thereupon passes through a projection lens 22 configured to image the mask structures onto the substrate 24. The projection exposure apparatus 10 can be embodied as a so-called scanner or a so-called stepper. The exposure radiation 14 is guided within the illumination optical unit 16 and the projection lens 22 via a plurality of optical elements, in the present case in the form of mirrors.

In the embodiment illustrated, the illumination optical unit 16 comprises four optical elements in the form of mirror elements 30-1, 30-2, 30-3 and 30-4. The projection lens 22 likewise comprises four optical elements in the form of mirror elements 30-5, 30-6, 30-7 and 30-8. The mirror elements 30-1 to 30-8 are arranged in an exposure beam path 28 of the projection exposure apparatus 10 for the purpose of guiding the exposure radiation 14.

In the embodiment shown, the mirror element 30-5 is part of an adaptive optical module 38, which may also be referred to as an adaptive optical element. In this case, the optical surface of the mirror element 30-5 serves as an active optical surface 32 of the adaptive optical module 38, the shape of which surface can be actively changed in order to correct local shape errors. In further embodiments, a different mirror element or a plurality of the mirror elements 30-1, 30-2, 30-3, 30-4, 30-5, 30-6, 30-7 and 30-8 can also each be configured as part of an adaptive optical module.

Furthermore, one or more of the mirror elements 30-1, 30-2, 30-3, 30-4, 30-6, 30-7 and 30-8 or the adaptive optical module 38 of the projection exposure apparatus 10 can be movably mounted. For this purpose, a respective rigid body manipulator is assigned to each of the movably mounted mirror elements. For example, the rigid body manipulators each enable a tilt and/or a displacement of the assigned mirror elements substantially parallel to the plane in which the respective reflective surface of the optical elements is located. Hence, the position of one or more of the mirror elements can be changed for the purpose of correcting imaging aberrations of the projection exposure apparatus 10.

In accordance with one embodiment, the projection exposure apparatus 10 comprises a control device 41 for generating control signals 42 for the provided manipulation units, such as the aforementioned rigid body manipulators, of one or more adaptive optical modules and/or possibly further manipulators. FIG. 1 illustrates by way of example the transmission of a control signal 42 to the adaptive optical module 38. In accordance with one embodiment for correcting aberrations of the projection lens 22, the control device 41 uses a feedforward control algorithm to ascertain the control signals 42 on the basis of wavefront deviations 46 of the projection lens 22 as measured via a wavefront measuring device 44.

One embodiment of the adaptive optical module 38 is illustrated in FIG. 2. The illustration in the upper section of FIG. 2 shows the adaptive optical module 38 in an initial state in which the shape of the optical surface 32 has an initial shape, a plane shape in this case. The illustration in the lower section of FIG. 2 shows the adaptive optical module 38 in a correction state in which the shape of the optical surface 32 has a changed shape, a convexly curved shape in this case.

The adaptive optical module 38 comprises a support element 34 in the form of a back plate and the mirror element 30-5, the top side of which forms the active optical surface 32 and serves to reflect the exposure radiation 14. A plurality of actuators 36, which are also referred to as manipulators, are arranged along the underside of the mirror element 30-5. In this case, these can be positioned both in the x-direction and in the y-direction, i.e. in a two-dimensional arrangement, along the underside of the mirror element 30-5. The actuators 36, only a few of which have been provided with a reference sign in FIG. 2 for reasons of clarity, connect the support element 34 to the mirror element 30-5. The actuators 36 are configured to change their extent along their longitudinal direction upon actuation. In the embodiment in accordance with FIG. 2, the actuators 36 are actuatable transversely or perpendicularly to the optical surface 32. The actuators 36 are each controlled individually and can therefore be actuated independently of one another. The adaptive optical module 38 can comprise more or fewer actuators 36 than the number illustrated in FIG. 2. In the correction state shown in the lower section of FIG. 2, centrally arranged actuators 36 have an increased length on account of actuation, thus resulting in the convexly curved shape for the optical surface 32.

For simplification, in subsequent figures, reference is made by way of example to three successively arranged actuators 36ₙ₋₁, 36ₙ and 36ₙ₊₁. In this case, n represents a counting variable for the actuators, where n=4 in the illustration in accordance with FIG. 2. In other words, the illustration of the actuators 36ₙ₋₁, 36ₙ and 36ₙ₊₁ in the subsequent figures mentioned serves by way of example to elucidate an adaptive optical module 38 having at least the three actuators mentioned, such as additional actuators 36 being present.

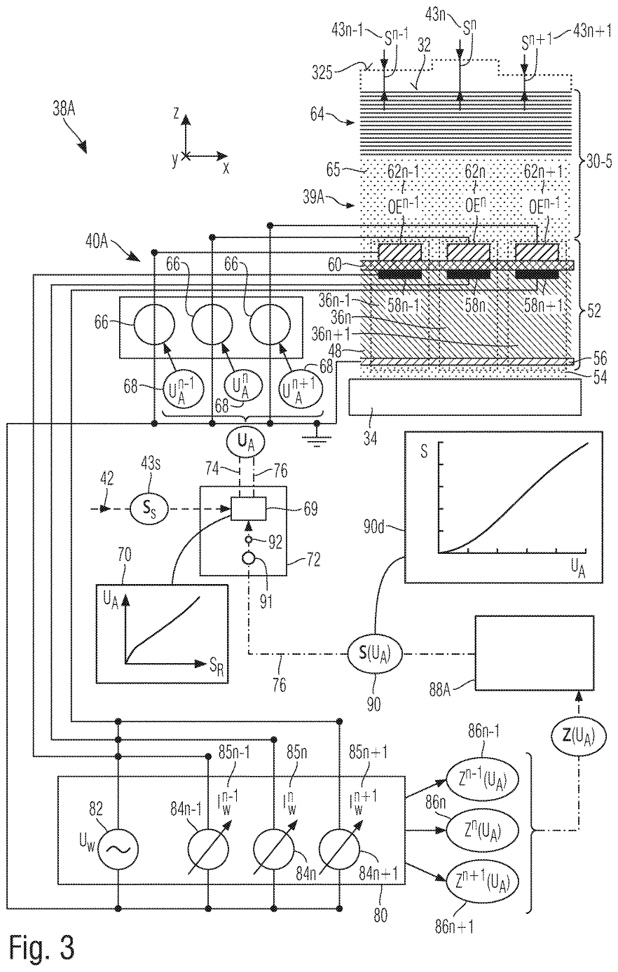

FIG. 3 illustrates the adaptive optical element 38 in accordance with FIG. 2 in an embodiment 38A in accordance with a first aspect of the disclosure by way of example having the three actuators 36n−1, 36n and 36n+1 mentioned above. The adaptive optical element 38A comprises a dielectric medium 48, which extends over the actuators 36n−1, 36n and 36n+1 and which is deformable by application of an electric field. This can be a piezoelectric material or an electrostrictive material. The deformation is based on the piezoelectric effect in the case of a piezoelectric material, while it is based on the electrostrictive effect in the case of an electrostrictive material. In this text, the electrostrictive effect is understood to mean the component of a deformation of a dielectric medium on the basis of an applied electric field, in which the deformation is independent of the direction of the applied field and, for example, proportional to the square of the electric field. In contrast thereto, the linear response of the deformation to the electric field is referred to as the piezoelectric effect.

In the embodiment variant described below, the actuators 36 are embodied as ferroelectric actuators, in which the dielectric medium 48 comprises a perovskite-based ceramic, and are based on the electrostrictive effect, i.e. the deformation of the dielectric medium 48 resulting from application of an electric field is based on the electrostrictive effect. The ferroelectric actuators are particularly well suited to correcting the shape of the active optical surface 32 since these have a very small drift and exhibit only a minor hysteresis.

The adaptive optical module 38A illustrated in FIG. 3 comprises a layer construction 39A and an electronics unit 40A. The layer construction 39A comprises the support element 34 in the form of a substrate, an actuator section 52 comprising the actuators 36n−1, 36n and 36n+1, and the mirror element 30-5. The construction of the actuator section 52 comprises, starting from the support element 34, an insulator layer 54, a base electrode 56, the abovementioned dielectric medium 48, measuring electrodes 58, a weakly conductive structure 60, here in the form of an LNO layer, and control electrodes 62. The LNO layer has approximately a conductivity of 20 S/m at 30° C. In general, the weakly conductive layer has a conductivity of at least 0.1 mS/m, for example of at least 1 mS/m, at least 0.01 S/m, at least 0.1 S/m or at least 10 S/m, but less than 1 kS/m, for example less than 200 S/m or less than 100 S/m. Advantageously, an insulation layer, not illustrated in the drawing, is arranged between the measuring electrodes 58 and the weakly conductive layer 60.

Each of the actuators 36n−1, 36n, and 36n+1 comprises a separate control electrode 62.

The control electrodes 62 are also referred to as upper electrodes OE, where the actuator 36n⁻¹ comprises the upper electrode OEⁿ⁻¹ (62n−1), the actuator 36n comprises the upper electrode OEⁿ (62n) and the actuator 36n⁺¹ comprises the upper electrode OEⁿ⁺¹ (62n+1). The base electrode 56 is grounded in the embodiment shown, serves as a counterelectrode for the control electrodes 62 and is furthermore embodied in continuous fashion, i.e. one piece, in the present embodiment. Alternatively, the base electrode 56 can also be divided into a plurality of individual electrodes, for example into in each case one individual electrode per actuator 36. These individual electrodes can then be kept at the same electrical potential via wire connections. The combination of the respective control electrode 62 with the base electrode serves for generating an electric field in the dielectric medium 48 in order to change the respective extent of the actuators 36.

The insulator layer 54 serves for electrically insulating the base electrode 56 with respect to the support element 34. For this purpose, the insulator layer can be fabricated e.g. from CNO (CNiO₃). The weakly conductive structure 60 in the form of the LNO layer is arranged below the control electrodes 62 and extends continuously along the control electrodes 62. It is used to smooth the deformation effect when individual actuators 36 are controlled. In this context, reference may be made to an arrangement of the actuators in coupled networks. By virtue of the weakly conductive LNO layer, leakage currents occur between the individual control electrodes 62 when different voltages are applied to the control electrodes 62, as a result of which a gradient field is created. LNO stands for LaNiO₃, this material having a conductivity of approximately 864 siemens/cm.

On account of the leakage currents mentioned, an impedance measurement of the actuators 36n−1, 36n and 36n+1 performed on the control electrodes 62 would lead to falsifications. In order to avoid these, in the embodiment illustrated in FIG. 3, each of the actuators 36n−1, 36n and 36n+1 furthermore comprises a measuring electrode 58n−1, 58n and 58n+1, respectively, used for measuring the impedance of the relevant actuator. The measuring electrodes 58 are each arranged directly below the LNO layer 60.

The mirror element 30-5 comprises a multilayer arrangement 64, also referred to as multilayer, and also a smoothing and insulation layer 65. The smoothing and insulation layer 65 is applied to the control electrodes 62 of the actuator section 52 and serves to produce a smooth bearing surface for the multilayer arrangement 64 pertaining to the electrical insulation of the multilayer arrangement 64 with respect to the control electrodes 62. The top side of the multilayer arrangement 64 forms the active optical surface 32 of the adaptive optical module 38A.

The control electrodes 62n−1, 62n and 62n+1 are each connected to a voltage generator 66 of the electronics unit 40A, whereby a controllable working voltage 68

$$( {U}_{A}^{n - 1} , {U}_{A}^{n} and {U}_{A}^{n + 1} , respectively )$$

designated by the reference sign 68 can in each case be generated relative to the base electrode 56. That is to say that the working voltage 68 is a DC voltage with a variable voltage value U_{A}.

In addition to the voltage generators 66, the electronics unit 40A comprises a control unit 72, a measuring device 80 and an evaluation device 88A. The electronics unit 40A or even just some parts of the electronics unit 40A can, as in the embodiment described here, be part of the adaptive optical module 38A or else can be arranged outside the adaptive optical element 38A, for example can be part of the control device 41 of the projection exposure apparatus 10.

The total change in the length extent (in the z-direction) of an individual actuator 36 when a working voltage 68 different than 0 V is applied is referred to as deflection S. The respective deflection Sⁿ⁻¹, Sⁿ and Sⁿ⁺¹ (cf. also reference signs 43n−1, 43n and 43n+1) of the actuators 36n−1, 36n and 36n+1 becomes visible at the top side of the multilayer arrangement 64. The deflections Sⁿ⁻¹, Sⁿ and Sⁿ⁺¹ lead to a changed topography 32s of the optical surface 32.

Before the adaptive optical module 38A is put into operation, a reference characteristic curve 70 between the deflection S and the working voltage U_{A} is optionally measured for each of the actuators 36n−1, 36n and 36n+1 in a so-called reference mode. In the reference mode, different values for the working voltage U_{A}, i.e. different operating points of the working voltage U_{A}, are set and the corresponding deflection S_{R} of the optical surface 32 of the relevant actuator 36 is measured for each of these values via a reference measuring module in the form of an interferometer.

In a control mode 74, a target deflection vector Sₛ is read in by the control unit 72. The target deflection vector Sₛ (reference sign 43s) is contained in the control signal 42 originating from the control device 41 in accordance with FIG. 1 and comprises target values for the deflections Sⁿ⁻¹, Sⁿ and Sⁿ⁺¹. The information flow in the control mode 74 is indicated using dashed lines in FIG. 3. A conversion formula 69 for ascertaining a predefined vector U_{A} for the individual working voltages

$${U}_{A}^{n - 1} , {U}_{A}^{n} and {U}_{A}^{n + 1}$$

from the specified target deflection vector Sₛ is stored in the control unit 72.

For example, the conversion formula 69 can be formed by profile curves of the working voltage U_{A} as a function of the target deflection Sₛ for the individual actuators 36. These profile curves are advantageously ascertained, before the adaptive optical module 38A is put into operation, from the reference characteristic curves 70 ascertained in the reference mode, which specify the profile of S_{R} as a function of U_{A} for the individual actuators 36. Alternatively, the conversion formula 69 can be ascertained via a calibration mode 76 described in greater detail below. During operation, the conversion formula 69 is corrected in ongoing fashion, as will be described in greater detail below.

For the target deflection vector Sₛ that has been read in, the control device 41 ascertains corresponding control values for the working voltage vector U_{A} on the basis of the conversion formula 69 and thereby controls the voltage generators 66. By virtue of the working voltages

$${U}_{A}^{n - 1} , {U}_{A}^{n} and {U}_{A}^{n + 1}$$

applied to the control electrodes 62n−1, 62n and 62n+1 by the voltage generators 66, the actuators 36n−1, 36n and 36n+1 are deflected accordingly. A calibration mode 76 for calibrating the conversion formula 69 is applied each time new working voltages U_{A} are set via the voltage generators 66, or at specific time intervals. The information flow in the calibration mode 76 is illustrated using a dash-dotted line in FIG. 3.

For implementing the calibration mode 76, the embodiment of the adaptive optical element 38A as illustrated in FIG. 3 comprises the abovementioned measuring device 80, which is assigned to the illustrated actuators 36n−1, 36n and 36n+1. The measuring device 80 comprises an AC voltage source 82 for generating an electrical measurement voltage 83 in the form of an AC voltage U_{w}, the AC voltage source being positioned in each case between the measuring electrodes 58n−1, 58n and 58n+1 and the base electrode 56. In accordance with a further embodiment, instead of one uniform AC voltage source 82, respective dedicated AC voltage sources can also be connected to the individual measuring electrodes 58n−1, 58n and 58n+1.

The measuring device 80 furthermore comprises a plurality of current measuring devices 84, specifically a respective current measuring device 84n−1, 84n and 84n+1 for each of the measuring electrodes 58n−1, 58n and 58n+1 for the purpose of measuring the current intensities

$${I}_{W}^{n - 1} , {I}_{W}^{n} and {I}_{W}^{n + 1}$$

following into the individual measuring electrodes 58 on account of the applied AC voltage U_{W}. On the basis of the AC voltage U_{W} and the measured current intensities

$${I}_{W}^{n - 1} , {I}_{W}^{n} and {I}_{W}^{n + 1} ,$$

measuring device 80 ascertains the resulting impedance Z in each case. This is done for a plurality of working voltages U_{A}, so that the result of the ascertainment is a working voltage-dependent impedance Zⁿ⁻¹(U_{A}), Zⁿ(U_{A}) and Zⁿ⁺¹(U_{A}) (cf. reference signs 86n−1, 86n and 86n+1) for each of the actuators 36n−1, 36n and 36n+1. The impedances 86n−1, 86n and 86n+1 forming the vector Z(U_{A}) are transmitted to the abovementioned evaluation device 88A.

In the evaluation device 88A, the impedances Zⁿ⁻¹(U_{A}), Zⁿ(U_{A}) and Zⁿ⁺¹(U_{A}) measured for the various actuators 36n−1, 36n and 36n+1 are converted into a respective deflection characteristic curve Sⁿ⁻¹(U_{A}), Sⁿ (U_{A}) and Sⁿ⁺¹(U_{A}). The deflection characteristic curves Sⁿ⁻¹(U_{A}), Sⁿ (U_{A}) and Sⁿ⁺¹(U_{A}) are illustrated in collective form with the vector S(U_{A}) (cf. reference sign 90) in FIG. 3, and one of them is illustrated by way of example in a diagram 90d. Each of the deflection characteristic curves Sⁿ⁻¹(U_{A}), Sⁿ (U_{A}) and Sⁿ⁺¹(U_{A}) represents the deflection 43n−1, 43n and respectively 43n+1 of the individual actuators 36n−1, 36n and 36n+1 as a function of the working voltage U_{A}. In other words, the evaluation device 88A is configured to calculate at least one actuator deflection from the measured impedances 86n−1, 86n and 86n+1.

In addition to other algorithms known to a person skilled in the art, for the conversion of the measured Zⁿ⁻¹(U_{A}), Zⁿ(U_{A}) and Zⁿ⁺¹(U_{A}) into the deflection characteristic curves Sⁿ⁻¹(U_{A}), Sⁿ (U_{A}) and Sⁿ⁺¹(U_{A}), the evaluation device may rely on the following procedure: A capacitance C of the relevant actuator 36 is calculated from the measured impedance Z. For this purpose, the respective actuator 36 is represented by an equivalent circuit diagram, for example a series circuit formed by a capacitor and an ohmic resistor. Disregarding the change in capacitance as a result of a small deformation Δd, the susceptibility χ can then be derived directly from the capacitance C. From this, the polarization P in the dielectric medium and, from the latter, the deflection S of the actuator can be determined via the following relationships: P=∫_{χf0}dE and S~P², where E denotes the electric field strength in the dielectric medium.

The deflection characteristic curves S(U_{A}) are transmitted to a comparison module 91 of the control unit 72. The latter compares the deflection characteristic curves S(U_{A}) with the reference characteristic curves 70 and brings about a corresponding correction 92 of the conversion formula 69 of the control unit 72 if deviations are found. Alternatively, the control unit 72 calculates the conversion formula 69 directly from the deflection characteristic curves S(U_{A}). In any case, in the control mode 74, the control unit 72 ascertains the control value of the working voltage U_{A} for the voltage generators 66 on the basis of the determined deflection characteristic curves S(U_{A}). In other words, the control unit 72 is configured, on the basis of the calculated actuator deflections in the form of the deflection characteristic curves S(U_{A}), to correct the respective control variables present at the assigned control electrodes 62n−1, 62n and 62n+1 in the form of

$${U}_{A}^{n - 1} , {U}_{A}^{n} and {U}_{A}^{n + 1} ,$$

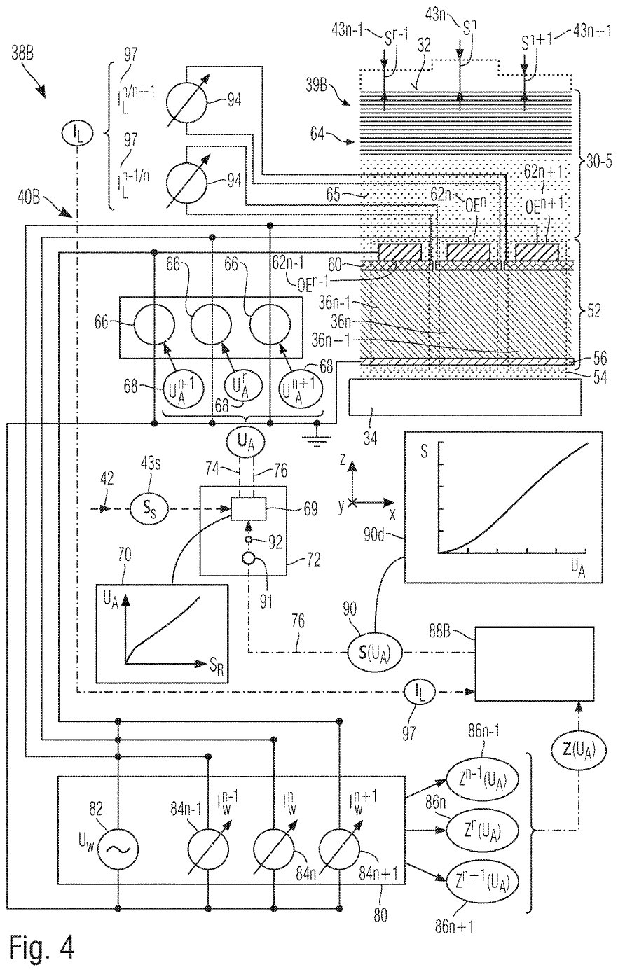

FIG. 4 illustrates the adaptive optical element 38 in accordance with FIG. 2 in an embodiment 38B in accordance with a second aspect of the disclosure, by way of example, having three actuators 36n−1, 36n and 36n+1. In this case, the embodiment 38B comprises a layer construction 39B and an electronics unit 40B. The layer construction 39B differs from the layer construction of the embodiment 38A in accordance with FIG. 3 in that no measuring electrodes 58 are provided in the actuators 36n−1, 36n and 36n+1, and in terms of the configuration of the weakly conductive structure 60.

The electronics unit 40B is configured to perform the impedance measurements of the actuators 36n−1, 36n and 36n+1 directly on the control electrodes 62n−1, 62n and 62n+1. The effect of the current flows caused by the weakly conductive structure 60, i.e. of the leakage currents mentioned above, between adjacent control electrodes 62 on the measurement result is computationally extracted from the measurement result of the relevant impedance measurement by the electronics unit 40B. In this text, an adjacent control electrode pertaining to a reference control electrode should be understood to mean any control electrode which is connected to the control electrode pertaining to the reference control electrode via the weakly conductive layer. The term “adjacent control electrode” thus covers both a control electrode that directly neighbors the reference control electrode, i.e. a control electrode that is directly adjacent to the reference control electrode, and a next but one or more remote control electrode neighbor.

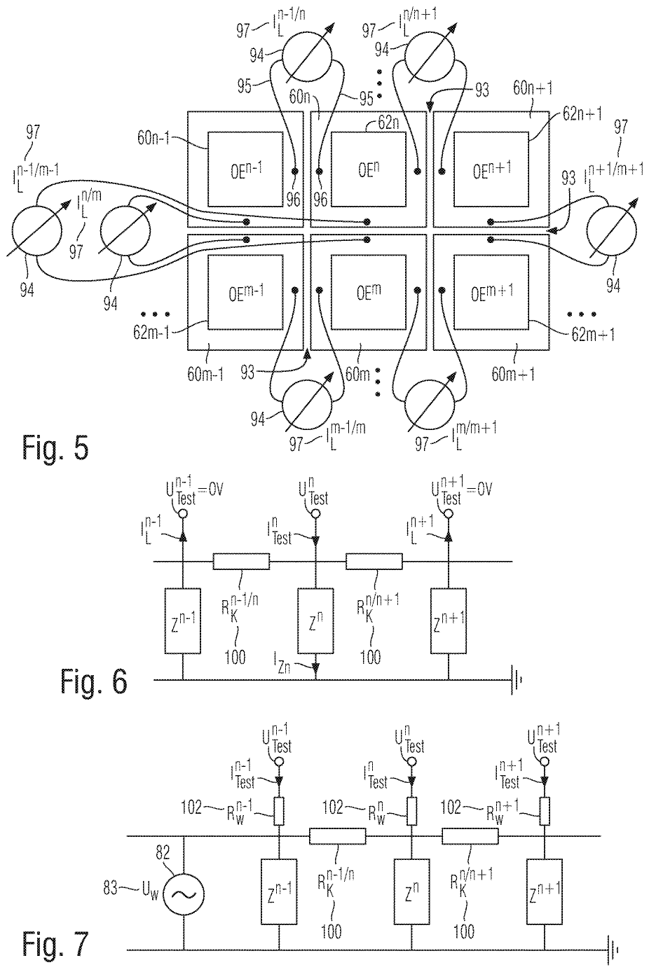

For this purpose, the weakly conductive structure 60 is divided into sections each assigned to one of the control electrodes 62, in the illustration in accordance with FIG. 4 the sections 60n−1, 60n and 60n+1. This design is also illustrated in a sectional view parallel to the xy-plane in FIG. 5. As is evident from FIG. 5, the sections of the weakly conductive structure in the illustrated configuration each have a square shape with a surface area exceeding the surface area of the respective control electrode 62 and are each arranged centered with respect to the relevant control electrode 62. In this regard, the sections 60n−1, 60n and 60n+1 are each centered with respect to the control electrode OEⁿ⁻¹ (reference sign 62n−1), OEⁿ and OEⁿ⁺¹ respectively. Analogously thereto, in a preceding series of actuators, the sections 60m−1, 60m and 60m+1 are centered with respect to control electrodes OE^{m-1}, OE^{m} and OE^{m+1} respectively. The arrangement can be continued correspondingly to the left, right, bottom and top, as indicated by continuation dots in FIG. 4.

The sections of the weakly conductive structure 60 are separated from the respective directly adjacent sections; for example, they are mutually separated from the respective directly adjacent sections by electrically insulating separation lines 93. In this regard, separation lines 93 run around the section 60n, so that the latter is electrically insulated from the sections 60n−1, 60n+1, 60m and any section that may be adjacent above. A respective current flow between these sections takes place only via a respective current measuring device 94. This current flow between two sections is the abovementioned leakage current between the relevant control electrodes 62. This leakage current can be accurately measured via the current measuring devices 94 in the embodiment described here.

For this purpose, the current measuring devices 94 are connected to the relevant sections via current lines 95 via respective contact points 61 arranged at the edge of the relevant section of the weakly conductive structure 60. In this regard, for example, the current measuring device 94 serving for measuring the leakage current

$${I}_{L}^{n - 1 / n}$$

is connected via respective current lines 95 to contact points 96 on the section 60n−1 and the section 60n.

The electronics unit 40B in accordance with FIG. 4 differs from the electronics unit 40A in accordance with FIG. 3 by virtue of the presence of the current measuring devices 94 for measuring the leakage currents 97 and in that the AC voltage source 82 and the current measuring devices 84 are not connected between the measuring electrodes 58 in accordance with FIG. 3 and the base electrode 56, but rather between the control electrodes 62n−1, 62n and 62n+1 and the base electrode 56. The ascertainment of the impedances Zⁿ⁻¹(U_{A}), Zⁿ(U_{A}) and Zⁿ⁺¹(U_{A}) carried out by the measuring device 80 is carried out analogously to the procedure described with reference to FIG. 4 on the basis of the AC voltage U_{W} applied by the AC voltage source 82 and the current intensities

$${I}_{W}^{n - 1} , {I}_{W}^{n} and {I}_{W}^{n + 1}$$

ascertained by the current measuring device 84n−1, 84n and 84n+1.

The functioning of the evaluation device 88B in accordance with FIG. 4 differs from the evaluation device 88A in accordance with FIG. 3 in that this takes into account the leakage currents 97 measured by the current measuring devices 94 in the ascertainment of the deflection characteristic curves 90 from the working voltage-dependent impedances 86. The totality of the leakage currents 97 is designated by a leakage current vector IL in FIG. 4. The leakage currents 97 are taken into account in the evaluation device 88B in such a way that the respective effect of the leakage currents on the current flows measured by the current measuring devices 84, i.e. on the current intensities

$${I}_{W}^{n - 1} , {I}_{W}^{n} and {I}_{W}^{n + 1} etc .$$

(cf. reference signs 85n−1, 85n, 85n+1), is computationally extracted from the measurement result of the impedances Zⁿ⁻¹(U_{A}), Zⁿ(U_{A}) and Zⁿ⁺¹(U_{A}) etc. The impedances corrected in this way are then used to determine the deflection characteristic curves 90.

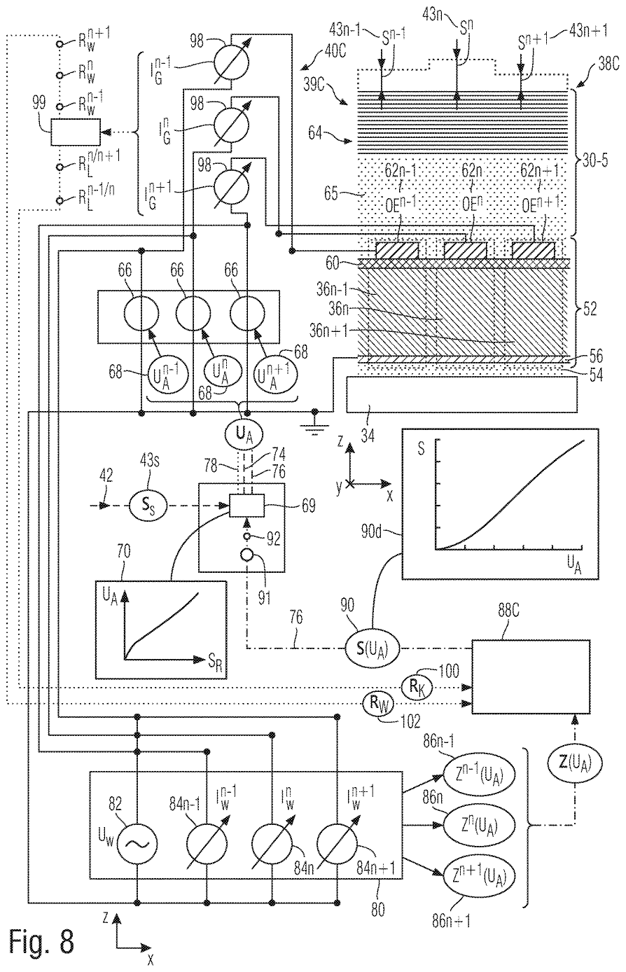

FIG. 8 illustrates the adaptive optical element 38 in accordance with FIG. 2 in a further embodiment 38C in accordance with the second aspect of the disclosure by way of example having three actuators 36n−1, 36n and 36n+1. In this case, the embodiment 38C comprises a layer construction 39C and an electronics unit 40C. The layer construction 39C differs from the layer construction of the embodiment 39B in accordance with FIG. 4 merely in that the weakly conductive structure 60, as in the embodiment 39A in accordance with FIG. 3, is configured as a layer extending continuously along the control electrodes 52.

The electronics unit 40C, like the electronics unit 40B in accordance with FIG. 4, is configured to perform the impedance measurements of the actuators 36n−1, 36n and 36n+1 directly on the control electrodes 62n−1, 62n and 62n+1. Furthermore, the electronics unit 40C is also designed to computationally extract from the measurement result of the relevant impedance measurement the effect of the leakage currents between adjacent control electrodes 62 on the measurement result, the leakage currents being caused by the weakly conductive structure 60. In contrast to the electronics unit 40B, in which the computational extraction is carried out on the basis of measurements of the leakage currents 97 actually flowing, the electronics unit 40C computationally extracts the effect of the leakage currents on the basis of predetermined coupling resistances R_{K} (reference sign 100) between the individual control electrodes 62 and the respective adjacent control electrodes 62.

In the embodiment illustrated in FIG. 8, current measuring devices 98 and a resistance ascertaining device 99 for determining the aforementioned coupling resistances 100 are already integrated into the electronics unit 40C. As already mentioned, the determination of the coupling resistances 100 is already carried out before operation of the adaptive optical module 38C in the calibration mode 76, which is carried out in the context of the exposure operation of the projection exposure apparatus 10. The determination of the coupling resistances 100 is carried out in a qualification mode 78, in which an electronics unit independent of the electronics unit 40C can also be used. Thus, in a further embodiment, not illustrated in the drawing, the electronics unit 40C can be designed just for implementing the control mode 74 and the calibration mode 76 and can thus be configured without the current measuring devices 98 and the resistance ascertaining device 99.

FIG. 6 illustrates an equivalent circuit diagram of the actuators 36n−1, 36n and 36n+1 of the adaptive optical module 38C for explaining the procedure for determining the coupling resistances 100. Zⁿ⁻¹, Zⁿ and Zⁿ⁺¹ represent the impedances of the actuators 36n-1, 36n and 36n+1 and

$${R}_{K}^{n - 1 / n} and {R}_{K}^{n / n + 1}$$

the coupling resistances 100 between the control electrodes 62n−1 and 62n and the control electrodes 62n and 62n+1. In order to determine the coupling resistances

$${R}_{K}^{n - 1 / n} and {R}_{K}^{n / n + 1}$$

in the qualification mode 78 via the corresponding voltage generator 66, a DC voltage,

$${U}_{Test}^{n}$$

is applied to the control electrode 62n and at the same time the voltage at the control electrodes 62n−1 and 62n+1 and all further adjacent control electrodes, if present, is set to

$$0 V ( {U}_{Test}^{n - 1} = 0 V , {U}_{Test}^{n + 1} = 0 V ) .$$

The DC currents

$${I}_{G}^{n - 1} and {I}_{G}^{n + 1}$$

corresponding to the leakage currents

$${R}_{K}^{n - 1 / n} and {R}_{K}^{n / n + 1}$$

through the coupling resistances

$${I}_{L}^{n - 1} and {I}_{L}^{n + 1}$$

are then measured via the current measuring devices 98.

The resistance ascertaining device thereupon ascertains the coupling resistances

$${I}_{L}^{n - 1} and {I}_{L}^{n + 1}$$

from the leakage currents

$${R}_{K}^{n - 1 / n} and {R}_{K}^{n / n + 1}$$

as follow:

$${R}_{K}^{n - 1 / n} = \frac{{U}_{Test}^{n}}{{I}^{n - 1}} and {R}_{K}^{n / n + 1} = \frac{{U}_{Test}^{n}}{{I}^{n * 1}} .$$

Coupling resistances with the respect to further adjacent control electrodes 62 are calculated analogously.

The coupling resistances 100 ascertained in this way (also illustrated as vector R_{K} in FIG. 8) are passed on to the evaluation device 88C and stored there. The functioning of the evaluation device 88C in accordance with FIG. 8 differs from the evaluation device 88B in accordance with FIG. 4 in that this takes into account the predetermined coupling resistances 100 instead of the directly measured leakage currents 97 in the ascertainment of the deflection characteristic curves 90 from the working voltage-dependent impedances 86. The coupling resistances 100 are taken into account in the evaluation device 88B in such a way that the respective effect of the respective leakage currents resulting from the coupling resistances on the current flows measured by the current measuring devices 84 is computationally extracted from the measurement result of the impedances Zⁿ⁻¹(U_{A}), Zⁿ(U_{A}) and Zⁿ⁺¹(U_{A}) etc. The impedances corrected in this way are then used to determine the deflection characteristic curves 90.

The determination of the leakage currents from the coupling resistances 100 is carried out in the evaluation device 88C on the basis of the equivalent circuit diagram illustrated in FIG. 6. By way of example, the current intensity I_{Zn} of the actuator 36n results from this as follows:

$${I}_{Z n} = {I}_{n} - \sum \frac{{U}_{n} - {U}_{i}}{{R}_{ni}} where i \neq n .$$

In this case, Iₙ denotes the current intensities of the adjacent actuators, Uₙ denotes the voltages at the adjacent actuators and Ui denotes the voltage at the actuator 36n.

Optionally, the evaluation device 88C can furthermore be configured to take account of line resistances

$${R}_{w}^{n - 1} , {R}_{w}^{n} and {R}_{w}^{n + 1}$$

(cf. reference sign 102) of the supply lines to the control electrodes 62n−1, 62n and 62n+1 when ascertaining the deflection characteristic curves 90 from the working voltage-dependent impedances 86. The line resistances 102 are taken into account in such a way that their respective effect on the measurement result of the impedances Zⁿ⁻¹(U_{A}), Zⁿ(U_{A}) and Zⁿ⁺¹(U_{A}) etc. is computationally extracted. The impedances corrected in this way are then used to determine the deflection characteristic curves.

The line resistances

$${R}_{w}^{n - 1} , {R}_{w}^{n} and {R}_{w}^{n + 1}$$

should be understood to mean the resistances of the connecting lines between the voltage generators 66 and the AC voltage source 82 with respect to the control electrodes 62n−1, 62n and 62n+1, including the contact resistances resulting from the contacting of the control electrodes 62n−1, 62n and 62n+1 by the connecting lines. The line resistances 102 are illustrated in an equivalent circuit diagram in FIG. 7.

In order to determine the line resistances 102, the frequency of the AC voltage source 82 is set to such a high frequency that a respective equivalent ohmic resistance of the actuators 36n−1, 36n and 36n+1 tends to zero, i.e. that the equivalent ohmic resistance is vanishingly low compared to the value of the relevant line resistance 102. That should be understood to mean that the respective equivalent ohmic resistance is less than 10%, for example less than 5%, of the value of the relevant line resistance. The frequency of the AC voltage source 82 set in this case can be for example at least 10 kHz, for example at least 100 kHz. In accordance with one embodiment, the frequency is in the range of 100 kHz to 1 MHz.

After the setting of the above-described high frequency at the AC voltage source 82, respective test voltages

$${U}_{Test}^{n - 1} , {U}_{Test}^{n} and {U}_{Test}^{n + 1}$$

are successively set at the individual control electrodes 62n−1, 62n and 62n+1 in each case via the voltage generators 66 and the respective resulting test current intensities

$${I}_{Test}^{n - 1} , {I}_{Test}^{n} and {I}_{Test}^{n + 1}$$

are measured via the current measuring devices 98. The resistance ascertaining device 99 ascertains the line resistance:

$${R}_{w}^{n} = \frac{{U}_{Test}^{n}}{{I}_{Test}^{n}} , {R}_{w}^{n - 1} and {R}_{w}^{n}$$

using the relationship

$${R}_{w}^{n + 1} .$$

The measuring function pertaining to the line resistances 102 and taking the latter into account in the ascertainment of the deflection characteristic curves 90 can optionally also be integrated into the adaptive optical module 38B in accordance with FIG. 4. In this embodiment, in addition to the configuration shown in FIG. 4, the optical module 38B also comprises the current measuring devices 98 illustrated in FIG. 8 and the resistance ascertaining device having the function for ascertaining the line resistances 102.

FIG. 9 shows a schematic view of a microlithographic projection exposure apparatus 210 configured for operation in the DUV wavelength range and comprising an illumination optical unit in the form of a beam shaping and illumination system 216 and comprising a projection lens 222. In this case, DUV stands for “deep ultraviolet” and denotes a wavelength of the exposure radiation 214 used in the projection exposure apparatus 210 of between 100 nm and 250 nm. The beam shaping and illumination system 216 and the projection lens 222 can be arranged in a vacuum housing and/or be surrounded by a machine room with corresponding drive devices.

The DUV projection exposure apparatus 210 comprises a DUV exposure radiation source 212. For example, an ArF excimer laser that emits exposure radiation 214 in the DUV range at, for example, approximately 193 nm can be provided for this purpose.

The beam shaping and illumination system 216 illustrated in FIG. 9 guides the exposure radiation 214 to a photomask 218. The photomask 218 is designed as a transmissive optical element and can be arranged outside the systems 216 and 222. The photomask 218 has a structure of which a reduced image is projected onto a substrate 224 in the form of a wafer or the like via the projection lens 222. The substrate 224 is displaceably mounted on a substrate displacement stage 226.

The projection lens 222 comprises a number of optical elements 230 in the form of lens elements and/or mirrors for projecting an image of the photomask 218 onto the substrate 224. In the embodiment illustrated, the optical elements 230 comprise lens elements 230-1, 230-4 and 230-5, the mirror 230-3 and the further mirror 230-2 embodied as an adaptive optical module 38. In this case, individual lens elements and/or mirrors of the projection lens 222 can be arranged symmetrically in relation to an optical axis 223 of the projection lens 222. It should be noted that the number of lens elements and mirrors of the DUV projection exposure apparatus 210 is not restricted to the number illustrated. More or fewer lens elements and/or mirrors can also be provided. Furthermore, the mirrors are generally curved on their front side for beam shaping purposes.

An air gap between the last lens element 230-5 and the substrate 224 can be replaced by a liquid medium 231 having a refractive index of >1. The liquid medium 231 can be high-purity water, for example. Such a setup is also referred to as immersion lithography and has an increased photolithographic resolution. The medium 231 may also be referred to as an immersion liquid.

In the exemplary embodiment shown in FIG. 9, the adaptive optical module 38 is embodied analogously to the adaptive optical module 38 in accordance with FIG. 1, although of course it comprises a different mirror element to that in FIG. 1. The adaptive optical module 38 is designed such that the shape of the surface 232 of the mirror 230-2 can be actively changed for the purpose of correcting local shape errors. The mirror surface is therefore also referred to as active optical mirror surface 232. In this case, the adaptive optical module 38 in accordance with FIG. 9 can be configured in one of the embodiments as illustrated in FIGS. 2, 3, 4 and 8. All explanations regarding the adaptive optical module 38 given above with reference to FIGS. 1 to 8 can thus be applied to the adaptive optical module 38 in accordance with FIG. 9.

Analogously to the projection exposure apparatus 10 in accordance with FIG. 1, the adaptive optical module 38 in accordance with FIG. 9 is controlled by control signals 42 which are ascertained by a control device 41 on the basis of wavefront deviations 46 of the projection lens 222 measured via a wavefront measuring device 44. Without restriction of generality, FIG. 9 here shows only one actuator device, but it is understood that a plurality of actuator devices can be present, each of which is able to be controlled individually by open-loop and/or closed-loop control.

The above description of exemplary embodiment examples, embodiments or embodiment variants should be understood to be by way of example. The disclosure effected thereby firstly enables a person skilled in the art to understand the present disclosure and the advantages associated therewith, and secondly encompasses alterations and modifications of the described structures and methods that are also obvious in the understanding of a person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10 Projection exposure apparatus
12 Exposure radiation source
14 Exposure radiation
16 Illumination optical unit
18 Mask
20 Mask displacement stage
22 Projection lens
24 Substrate
26 Substrate displacement stage
28 Exposure beam path
30-1, 30-2, 30-3, 30-4, 30-5, 30-6, 30-7, 30-8 Mirror elements
32 Active optical surface
34 Support element
36, 36n−1, 36n, 36n+1 Actuator
38, 38A, 38B, 38C Adaptive optical module
39A Layer construction
39B Layer construction
39C Layer construction
40A Electronics unit
40B Electronics unit
40C Electronics unit
41 Control device
42 Control signal
43 Deflection
43s Target deflection vector
44 Wavefront measuring device
46 Wavefront deviations
48 Dielectric medium
52 Actuator section
54 Insulator layer
56 Base electrode
58, 58n−1, 58n, 58n+1 Measuring electrode
60 Weakly conductive structure
62, 62n−1, 62n, 62n+1 Control electrode
64 Multilayer arrangement
65 Smoothing and insulation layer
66 Voltage generator
68 Working voltage
69 Conversion formula
70 Reference characteristic curve
72 Control unit
74 Control mode
76 Calibration mode
78 Qualification mode
80 Measuring device
82 AC voltage source
83 Measurement voltage
84, 84n−1, 84n, 84n+1 Current measuring device
85n−1, 85n, 85n+1 Current intensity
86n−1, 86n, 86n+1 Working voltage-dependent impedance
88A Evaluation device
88B Evaluation device
88C Evaluation device
90 Deflection characteristic curves
90d Diagram of a deflection characteristic curve
91 Comparison module
92 Correction
93 Electrically insulating separation line
94 Current measuring device
95 Current line
96 Contact point
97 Leakage current
98 Current measuring device
99 Resistance ascertaining device
100 Coupling resistance
102 Line resistance
210 Projection exposure apparatus
212 Exposure radiation source
214 Exposure radiation
216 Beam shaping and illumination system
218 Photomask
222 Projection lens
223 Optical axis
224 Substrate
226 Substrate displacement stage
230 Optical element
230-1, 230-4, 230-5 Lens element
230-2 Adaptive optical module
230-3 Mirror
231 Liquid medium
232 Active optical mirror surface

1. A module, comprising:
an optical surface configured to interact with exposure radiation of a projection exposure apparatus; and
a plurality of actuators configured to change a shape of the optical surface;
a dielectric medium configured to deform when an electrical voltage is applied thereto;
a plurality of separate control electrodes;
a weakly conductive structure having an electrical conductivity of at least 0.1 mS/m; and
a plurality of measuring electrodes,
wherein:
each actuator has a corresponding control electrode configured to generate an electric field in a layer of the dielectric medium;
the control electrodes are connected to one another via the weakly conductive structure; and
for each actuator, a corresponding measuring electrode is between the corresponding control electrode and the dielectric medium so that measuring electrode is configured to measure an impedance of the actuator.

2. The module of claim 1, wherein the weakly conductive structure is a layer between the control electrodes and the dielectric medium.

3. The module of claim 1, wherein the layer of the weakly conductive structure extends continuously along the control electrodes of the actuators.

4. The module of claim 1, further comprising a base electrode, wherein:
the base electrode is a counterelectrode with respect to the control electrodes; and
for each actuator, the base electrode is configured to generate, together with the corresponding control electrode, the electric field in the dielectric medium.

5. The module of claim 1, further comprising an evaluation device configured to calculate an actuator deflection from a measured impedance of one of the actuators.

6. The module of claim 5, further comprising a control unit configured to correct a control variable present at the assigned control electrode on the basis of the calculated actuator deflection.

7. A microlithographic projection exposure apparatus comprising a module according to claim 1.

8. A method of using a microlithographic projection exposure apparatus comprising an illumination optical unit and a projection optical unit, the method comprising:
using the illumination optical unit to illuminate an object in an object field of an object plane of the projection optical unit; and
using the projection optical unit to image the illuminated object into an image plane in an image field of the projection optical unit,
wherein the projection optical unit comprises a module according to claim 1.

9. A module, comprising:
an optical surface configured to interact with exposure radiation of a projection exposure apparatus; and
a plurality of actuators configured to change a shape of the optical surface;
a dielectric medium configured to deform when an electrical voltage is applied thereto;
a plurality of separate control electrodes;
a weakly conductive structure having an electrical conductivity of at least 0.1 mS/m; and
an evaluation device,
wherein:
each actuator has a corresponding control electrode configured to generate an electric field in a layer of the dielectric medium;
the control electrodes are connected to one another via the weakly conductive structure; and
the evaluation device is configured so that, when measuring an impedance of one of the actuators, the evaluation device computationally extracts from the measurement result an effect, influencing the measurement result, of a current flow between the corresponding control electrode and at least one of the other control electrodes, the current flow being caused by the weakly conductive structure.

10. The module of claim 9, further comprising a current measuring device configured to measure the current flow, wherein the evaluation device is configured to computationally extract the effect from the measurement result based on the measured current flow.

11. The module of claim 10, wherein the weakly conductive structure comprises a plurality of sections, each section is supported by the control electrode of the actuator being measured, each section is supported by the other control electrode, and the sections are electrically conductively connected via the current measuring device.

12. The module of claim 11, wherein the sections of the weakly conductive structure are electrically insulated from one another with the exception of the connection via the current measuring device.

13. The module of claim 11, wherein each section of the weakly conductive structure is supported by the control electrode of the actuator being measured and by the control electrodes of all actuators directly adjacent to the actuator being measured, and wherein the section of the actuator being measured is electrically conductively connected to each of the sections arranged on the directly adjacent actuators via a dedicated current measuring device.

14. The module of claim 9, wherein the evaluation device is configured to computationally extract from the measurement result the effect based on at least one predetermined coupling resistance between the control electrode of the actuator being measured and the at least one further control electrode.

15. The module of claim 14, further comprising a current measuring device configured to measure a current flow emerging from the control electrode when a test voltage is applied to the control electrode of the actuator being measured.

16. The module of claim 9, further comprising a voltage source connected to at least one of the control electrodes, wherein the evaluation device is configured, during the measurement of the impedance of the at least one control electrode, to computationally extract from the measurement result a line resistance from the voltage source to the control electrode.

17. The module of claim 16, further comprising an AC voltage source configured, for the purpose of determining the line resistance of the at least one control electrode, to apply to the at least one control electrode an AC voltage having such a high frequency that an equivalent ohmic resistance of the actuator assigned to the control electrode decreases to less than 10% of the value of the line resistance.

18. The module of claim 9, further comprising a measuring device configured, during the measurement of the respective impedance of the actuators, to measure a current intensity flowing away from the respective control electrode.

19.-22. (canceled)

23. A method of ascertaining a respective deflection of a plurality of actuators of an adaptive optical module of a microlithographic projection exposure apparatus, which are configured to change a shape of an optical surface of the optical module, the adaptive optical module comprising a dielectric medium which is deformable by an electrical voltage, each actuators having a separate control electrode to generate a respective electric field in a layer of the dielectric medium, control electrodes being connected to one another by a weakly conductive structure having an electrical conductivity of at least 0.1 mS/m, the method comprising:
measuring an impedance of an actuators using a measuring electrode arranged between the control electrode of the actuator and the dielectric medium; and
calculating the respective deflection of the actuators from the respective measured impedance.

24. A method of ascertaining a respective deflection of a plurality of actuators of an adaptive optical module of a microlithographic projection exposure apparatus, the actuators configured to change a shape of an optical surface of the optical module, the adaptive optical module comprising a dielectric medium which is deformable by an electrical voltage, each actuator having a separate control electrode to generate a respective electric field in a layer of the dielectric medium, control electrodes being connected to one another by a weakly conductive structure having an electrical conductivity of at least 0.1 mS/m, the method comprising:
measuring an impedance of an actuator;
computationally extracting an effect of a current flow caused by the weakly conductive structure from the measurement result of the impedance measurement, wherein the current flow takes place between the control electrode of the actuator being measured and at least one further of the control electrodes; and
calculating the respective deflection of the actuators from the respective measured impedance.

25.-28. (canceled)
